(19) United States
(12) Patent Application Publication
(10) Pub. No.: US 2005/0088192 A1
(43) Pub. Date: Apr. 28, 2005

(54) Method of manufacturing contact, contact made by the method, and inspection equipment or electronic equipment having the contact

(75) Inventors: Tsuyoshi Haga, Ako-gun (JP); Kousuke Miura, Ako-gun (JP); Jun Yorita, Ako-gun (JP)

Correspondence Address: MCDERMOTT WILL & EMERY LLP, 600 13TH STREET, N.W., WASHINGTON, DC, 20005-3096, US

(73) Assignee: SUMITOMO ELECTRIC INDUSTRIES, LTD.

(21) Appl. No.: 10/972,482

(22) Filed: Oct. 26, 2004

(30) Foreign Application Priority Data
Oct. 27, 2003 (JP) 2003-366037
Mar. 5, 2004 (JP) 2004-062212

(51) Int. Cl. G01R 31/02

(52) U.S. Cl. 324/754

(57) ABSTRACT

A method of manufacturing a columnar contact having a spiral spring structure for attaining electrical continuity with an electrode of electronic equipment or inspection equipment, the method comprising the steps of forming a plastic mold (resist structure) with a metal mold; forming a layer consisting of metallic material on the plastic mold (resist structure) by means of electroforming. With such method, an inspection contact or coupling contact having high reliability and capable of attaining electrical continuity of large electric current can be produced at low cost.

### BACKGROUND OF THE INVENTION

1. Field of the Invention

The present invention relates to a contact used for taking out an electrical signal from an electrode of electronic equipment having an IC or LSI, etc. by pressing the contact onto the electrode. The invention also relates to inspection equipment and electronic equipment which are equipped with such contacts.

2. Description of the Background Art

An inspection socket is used for taking out electrical signals from electrodes of electronic equipment having an IC or LSI, etc. through contacts by pressing the contacts to the electrodes in order to inspect the electrical continuity of the electronic equipment. A connector is used for the purpose of maintaining electrical continuity with electronic equipment in a manner such that contacts are pressed on the land electrodes of the electronic equipment so as to maintain electrical continuity with the electronic equipment through the contacts. Generally, the inspection socket and connector are provided with a number of contacts corresponding to the number of the electrodes of the electronic equipment to be connected. Therefore, higher density corresponding to high density of electrodes provided in electronic equipment is demanded of the contacts to be provided in the inspection socket and the connector.

One of such known contacts is, for example, a contact for BGA (ball grid array). The contact has a planar spiral shape before contacting a ball electrode, and the spiral shape of the contact changes corresponding to the shape of the ball electrode as a result of contacting with the ball electrode (see Japanese Patent Application Publication No. 2002-175859). It is described therein that this contact can comply with high density of electrodes, securing electrical continuity without deforming a ball electrode and being highly reliable.

In the case of using a spiral contact, the sag amount of the spiral increases as distanced from the tip part of the ball electrode while the sag amount of the spiral is small at the tip part. Accordingly, the bending stress is the largest near the root of the spiral contact, where the sag amount is the largest. Therefore, the reliability of the spiral contact decreases according to the increase in the mounting density of ball electrodes. In a known method to solve such a problem, the shape of an electrode on the side of electronic equipment is designed to be a circular cone, triangular pyramid, quadrangular pyramid, or the like (see Japanese Patent Application Publication No. 2003-78078).

In a known method for preventing the decrease of voltage in a processing circuit for high-speed signal and thereby preventing the degradation of reliability caused by miniaturization of electronic equipment and high density mounting of electrodes, spiral contacts and condensers are connected in a state where condensers are arranged at the vicinity of spiral contacts (see Japanese Patent Application Publication No. 2003-149293). Further, it is stated that as a result of providing such spiral contacts at both faces of an insulative substrate, high density packaging is possible and high frequency electrical characteristics are improved.

These spiral contacts are manufactured by various methods, such as a method in which a plating method is combined with a lithography method that uses ultraviolet radiation (UV) having a wavelength of about 200 nm, a method that uses laser, etching or punching. However, with the lithography method using UV, or the methods using laser, etching or punching, only spiral contacts having a thickness of about 20 μm or less can be produced, and consequently the aspect ratio is small. Accordingly, the spring must be thinner if it is attempted to increase a stroke (sag amount of a spiral) in order to obtain a contact having high conduction reliability. Therefore, with such a contact, it is impossible to attain electrical continuity of a large electric current of 0.5 A or more.

Also, because of the small aspect ratio, the number of spirals becomes less, and the contact load decreases when the stroke is attempted to be enlarged, whereas the stroke decreases when the contact load is attempted to be increased. Therefore, only spiral contacts of low coupling reliability are obtained. Moreover, because of a large number of parts such as a spiral contact, interposer board with VIA, etc., the cost of parts increases, and the assembling cost increases because alignment is necessary in assembling, which results in high cost of the contact.

### SUMMARY OF THE INVENTION

The present invention was accomplished in view of the above-mentioned problems, and an object of the invention is to provide a low cost inspection or coupling contact having high reliability and capable of attaining electrical continuity of large electric current.

A method of manufacturing a contact according to the present invention is a manufacturing method for a columnar contact having a spiral spring structure that is used for attaining electrical continuity with a convex electrode of electronic equipment or inspection equipment by pressing the contact on the electrode. The shape of the contact changes according to the shape of the convex electrode when the contact is pressed on it. The method typically includes a process of forming a plastic mold (resist structure) with a metal mold, a process of forming a layer consisting of metallic material in the plastic mold (resist structure) by means of electroforming.

Another manufacturing method of a contact of the present invention typically includes a process of forming a plastic mold (resist structure) by X-ray lithography, a process of forming a layer consisting of metallic material in the plastic mold (resist structure) by electroforming.

Such manufacturing methods may further include a process of machining one or both faces of the layer consisting of metallic material so that the thickness of the layer consisting of metallic material becomes thinner from the outer periphery to the center. Such machining process may be performed by electrical discharge machining. Such machining process may be performed in a manner such that one or both faces of the layer consisting of metallic material can be in contact with a spherical face or paraboloid of revolution after the machining thereof. The contact of the present invention may be manufactured by such methods and may be made of nickel or nickel alloy. A connector conductor of the present invention may have a space between the contacts, which are arranged at both end portions of the connector conductor, so that the spring of a contact can perform a stroke. For example, the connector conductor may have a ring between the contacts thereof, or may consist of two contacts having a shape such that the thickness thereof becomes thinner radially from the outer periphery to the center.

The connector conductor may be structured such that a contact and another contact, or a contact and a ring, are connected together with or without being bonded. Such bonding may be done by ultrasonic junction, resistance junction or electromagnetic junction. Such bonding may be done after a layer consisting of a eutectic material is formed on a junction surface. Also, such bonding may be done after a layer consisting of a material having low contact resistance with respect to the convex electrode of electronic equipment or inspection equipment has been formed on the contact and a layer consisting of material having eutectic with respect to the material of the contact has been formed on the ring.

The inspection equipment of the present invention may have a socket equipped with such connector conductor in an insulative through-hole of a substrate and may be used for the inspection of semiconductors of land grid array arrangement. On the other hand, the electronic equipment of the present invention may have a connector equipped with such connector conductor in an insulative through-hole of a substrate, and may be connected with land electrodes.

According to the present invention, an inspection contact or coupling contact with high reliability which can attain electrical continuity of large electric current can be provided at low cost.

### BRIEF DESCRIPTION OF THE DRAWINGS

FIG. 1 is a perspective view of a contact of the present invention.

FIG. 2(a) is a sectional view showing a state in which contacts of the present invention are used as parts of an inspection socket. FIG. 2(b) is an enlarged view showing a state in which a contact is transformed when the contacts of the present invention shown in FIG. 2(a) are used as parts of the inspection socket.

FIGS. 3(a)-3(c) schematically show a process of manufacturing an inspection socket using contacts according to the present invention.

FIGS. 4(a)-4(f) schematically show a process of manufacturing a contact of the present invention.

FIGS. 5(a)-5(h) show another process of manufacturing a contact of the present invention.

FIGS. 6(a)-6(c) show cross-sections of contacts of the present invention, showing cross-sections cut perpendicularly relative to a longitudinal direction.

FIGS. 7(a)-7(d) are sectional views of contacts of the present invention, showing cross-sections cut in a longitudinal direction.

FIG. 8(a) is a sectional view showing a state in which contacts of the present invention are used as parts of an inspection socket. FIG. 8(b) is a sectional view showing a manner in which the contacts of the present invention shown in FIG. 8(a) are used being placed between a convex electrode on the transformer of inspection equipment and a convex electrode of semiconductor (LSI) in a case where the contacts are used as parts of an inspection socket.

FIGS. 9(a)-9(c) are views in which a method of joining a ring and contacts of the present invention is schematically shown.

### DETAILED DESCRIPTION OF THE INVENTION

Hereinafter, embodiments of the contacts of the present invention will be described in detail with reference to the accompanying drawings. In the description of the drawings, the same elements will be denoted by the same reference symbols, and redundant description will be omitted.

(Contact)

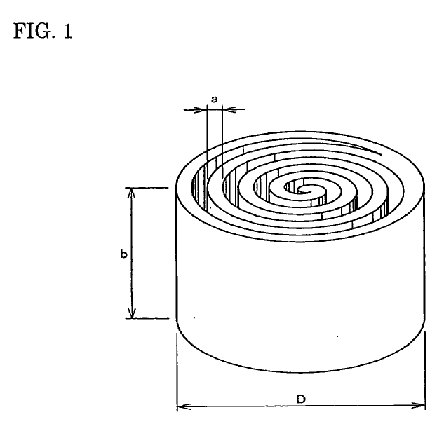

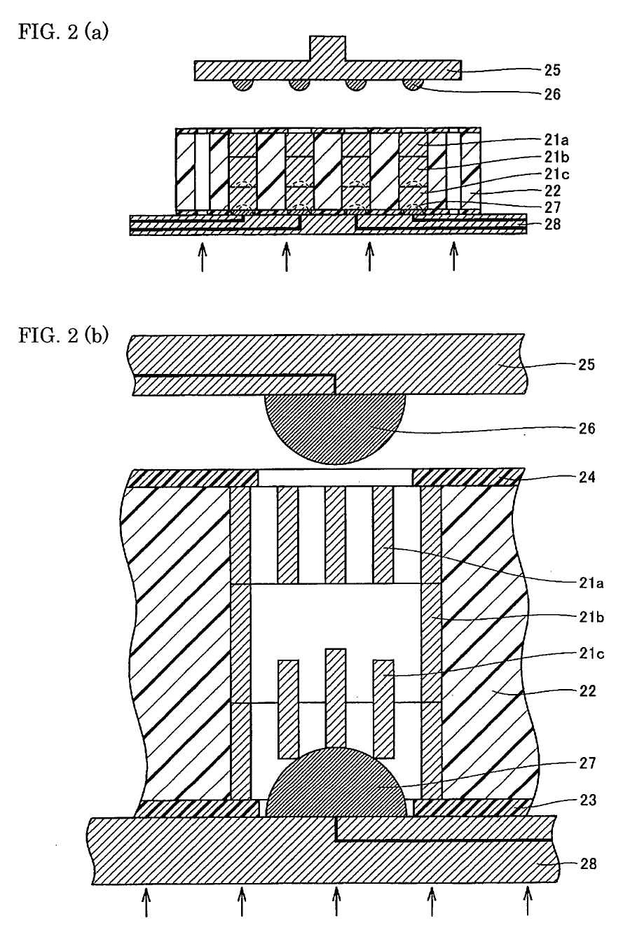

A typical example of a contact of the present invention is shown in FIG. 1. As shown in FIG. 1, the contact of the present invention is of columnar shape having a spiral spring structure, and is used as a part of a connector to be mounted in electronic equipment or the like or a part of an inspection socket for inspecting a semiconductor. An example of a case in which such contacts are used as parts of an inspection socket is shown in FIGS. 2(a) and 2(b). In the example illustrated in FIG. 2(a), an inspection socket is used for inspecting the electrical continuity of a semiconductor (LSI) 25 in a manner such that the inspection socket is put between the LSI 25 and a transformer 28 of measuring equipment.

The inspection socket has a connector conductor inserted in an insulative through-hole of the substrate thereof. The connector conductor is used in order to attain electrical continuity by connecting with a convex electrode of inspection equipment. Such connector conductors are formed in insulative through-holes of the substrate so that the mutual electrical insulation thereof is secured. The connector conductor has contacts of the present invention and a space where the spring of the contact can perform a stroke is provided between the contacts. For example, as shown in FIG. 2(a), a ring 21b and a couple of contacts 21a and 21c are provided in an insulative substrate 22 in a manner such that the ring 21b is arranged between the contacts 21a and 21c. In this example, the connector conductor is constituted by the ring 21b and the contacts 21a and 21c. When a convex electrode 27 provided on a transformer former 28 of inspection equipment is pressed onto the contact 21c of the inspection socket, the contact 21c is transformed according to the shape of the convex electrode 27.

FIG. 2(b) is an enlarged view illustrating a condition in which the contact 21c is transformed. As shown in FIG. 2(b), the contact 21c is transformed according to the shape of the convex electrode 27 as a result of being pressed by the convex electrode 27. Because of the spiral spring structure of the contact 21c, a degree of contact load is caused between the contact 21c and the convex electrode 27. A ring 21b functions to secure a space in which the contacts 21a and 21c can perform a stroke without touching each other. Also, the ring 21b eliminates the need of using an expensive through-hall electrode substrate, and substantial cost reduction can be achieved accordingly. The top face and the bottom face of the substrate 22 are provided with an upper-cover sheet 24 and a lower-cover sheet 23, respectively, and holes formed in these cover sheet are designed to be smaller than the outer diameter of the contacts so that the contacts 21a and 21c and the ring 21b do not drop from the substrate 22.

Similarly, when a convex electrode 26 of the LSI 25 is pressed onto the contact 21a, the contact 21a is transformed according to the shape of the convex electrode 26. Therefore, an electrical signal from LSI 25 is transmitted through the convex electrode 26, and then inside the insulative substrate 22 from the contact 21a, ring 21b, contact 21c, to the convex electrode 27 in the enumerated order, and finally to a transformer 28 of inspection equipment, and thus electrical continuity is obtained between the LSI 25 and the transformer former 28.

The contact of the present invention can connect an electrode of a LSI and an electrode of inspection equipment directly and the distance of connection is short. Accordingly, the contact can easily attain electrical continuity of high frequency electric current and large electric current, and it is advantageous in complying with high density of electrodes. Therefore, the contact of the present invention is useful as a contact of a socket for inspection equipment used for inspecting a semiconductor of land grid array arrangement, and the like. Similarly, the contact of the present invention is useful as a contact of a connector used for connection with land electrodes of communication equipment such as a cellular phone or electronic equipment such as a personal computer.

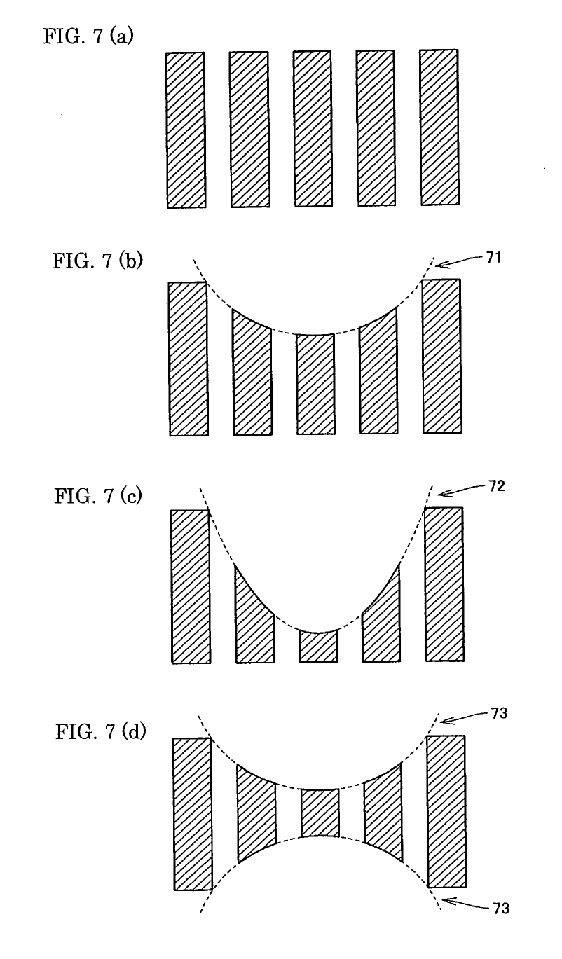

FIGS. 7(a) to 7(d) each show a sectional view of a contact of the present invention in the case where it is cut in a longitudinal direction. FIG. 7(a) shows an example of a contact having a spiral spring of uniform thickness. FIGS. 7(b) to 7(d) each show an example in which the thickness of the spiral spring of a contact is made to be thinner from the outer periphery toward the center. If the thickness and the width of the spiral spring are uniform, the stiffness of the spiral spring is larger at an inner part than at an outer part because the radius of curvature is less at a position closer to the center. However, if the thickness of the spiral spring of the contact is designed to be thinner at a position closer to the center, the stiffness becomes equal at any part, and consequently the whole of the spring exhibits uniform and efficient performance according to the shape of a convex electrode. Also, the stiffness can be made uniform by making the width of the spiral spring to be shorter at a position closer to the center. However, such a spiral spring has a shortcoming in that an outer peripheral part becomes thicker, and accordingly the number of spirals becomes less such that the stroke decreases. Therefore, the embodiment of the present invention in which the thickness is made thinner at a position closer to the center is more preferable.

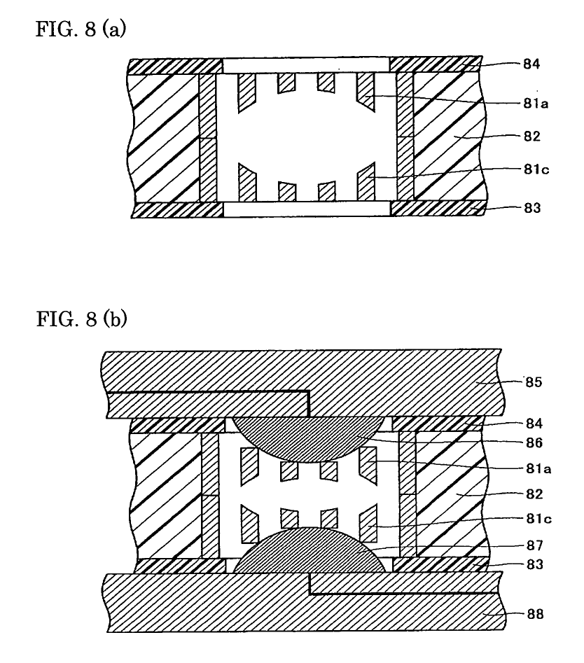

An example of an inspection socket using a contact whose spiral spring has a thickness that is thinner at a position closer to the center than at a position in an outer peripheral part is shown in FIGS. 8(a) and 8(b). As shown in FIG. 8(a), this inspection socket is equipped with two contacts 81a and 81c in an electrically insulative substrate 82 and is provided with an upper-cover sheet 84 and a lower-cover sheet 83 on the top and bottom thereof, respectively. Unlike the example of FIGS. 2(a) and 2(b), no ring is provided between the two contacts 81a and 81c. The connector conductor consists of two contacts whose spiral spring has a thickness that is thinner at a position closer to the center. Therefore, it is possible to secure a space that is necessary for the contacts to perform a stroke when they are put between a convex electrode 87 on a transformer former 88 of inspection equipment and a convex electrode 86 of a semiconductor (LSI) 85 as shown in FIG. 8(b). Therefore, it is advantageous for the connection of a high frequency electric current and a large electric current since the elimination of a ring results in the reduction of connection distance.

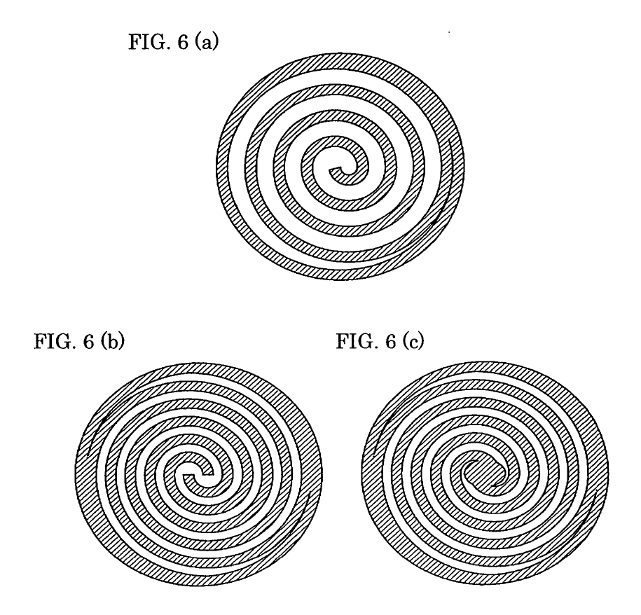

An electrode used in inspection equipment or electronic equipment has a convex shape so that sure contact can thereby be achieved between the contact and the electrode. Such a convex electrode is a ball electrode of BGA or a bump electrode formed by plating, for example. FIG. 1 shows an example of a contact having a cross-section substantially circular when cut in a plane perpendicular to a longitudinal direction. However, the shape of the contact of the present invention is not limited to such a circular shape; it may be a circular or elliptical shape having a partly warped circumference, or a polygonal shape, such as a triangle, square, etc. according to the shape of the convex electrode, or the like. The polygonal shape may have sides of different length, not limited to a regular polygon. FIG. 6 shows contacts of various modes of circular shape in a case where they are cut in a plane perpendicular to a longitudinal direction. They are all included in the scope of the present invention. The example shown in FIG. 6(a) consists of one arm. The examples shown in FIGS. 6(b) and 6(c) consist of two arms. In the example of FIG. 6(b), the tip is not connected, but in the example of FIG. 6(c), the tip is connected in the center.

(Method of Manufacturing a Contact)

The manufacturing method of the present invention for the contact typically includes a process of forming a plastic mold (resist structure) by X-ray lithography, and a process of forming a layer consisting of metallic material by electroforming in the plastic mold (resist structure). With such method, an inspection contact having high reliability and capable of attaining electrical continuity of large electric current can be produced at low cost.

In the manufacturing method of the present invention, X-rays (wavelength of 0.4 nm) which are shorter wavelength than UV (wavelength of 200 nm) are used because a contact having a high aspect ratio can thereby be obtained. In particular, synchrotron X rays (hereinafter, called “synchrotron radiation”) among the X-rays are preferably used in view of their high directivity. The LIGA (Lithographie Galvanoformung Abformung) process which uses synchrotron radiation is advantageous because deep lithography is possible with it, whereby metal microstructures having a height of several hundreds μm order can be produced with precision of micron order and in large quantities.

With a method in which X-rays and electroforming are used in combination, contacts having an aspect ratio (b/a) equal to or more than 2 as shown in FIG. 1 can be easily manufactured, and it is possible to manufacture contacts having an aspect ratio equal to or more than 30. Since a high aspect ratio can be obtained, it is possible to make the thickness b to be thick even if the width a of a spring is designed to be thin, and accordingly it is possible to produce contacts exhibiting high contact strength and high contact reliability. Also, it is possible to secure the conduction of a large permissible electrical current equal to or more than 0.5 A. Moreover, since the width a of the spring can be designed to be thin, the number of spirals can be increased. Accordingly, it is possible to produce spiral contacts exhibiting a large stroke of the spring. Thus, even if the stroke is made larger, the contact load does not decrease. More specifically, contacts having a spiral spring of two or more spirals can easily be manufactured, and it is possible to manufacture contacts having a spiral spring of four or more spirals in order to enhance a stroke. It is possible to easily produce contacts having a stroke of 100 μm or more and a contact load of 0.03 N or more. Moreover, contacts having a contact load of 0.1 or more can also be manufactured.

If an attempt is made to manufacture a spiral contact by machining such as curling of a plate, there is a limit to miniaturization of the contact, and a possible smallest spiral contact that can be made by such machining process will have a thickness b of 1000 μm and a diameter D of about 500 μm-1000 μm. With this size, it is difficult to comply with high density packaging of semiconductors. It is also difficult to manufacture precision contacts in large quantities, precisely with satisfactory reproducibility.

According to the present invention, it is possible to comply with the high density packaging of electronic equipment since contacts having a thickness b of 50 μm-500 μm and a diameter D of 100 μm-500 μm can easily be manufactured precisely with satisfactory reproducibility and in large quantities. Moreover, because of the manufacturing method in which lithography and electroforming are combined, the microstructure can be formed integrally, the number of parts can be decreased, and the part cost and assembling cost can be reduced.

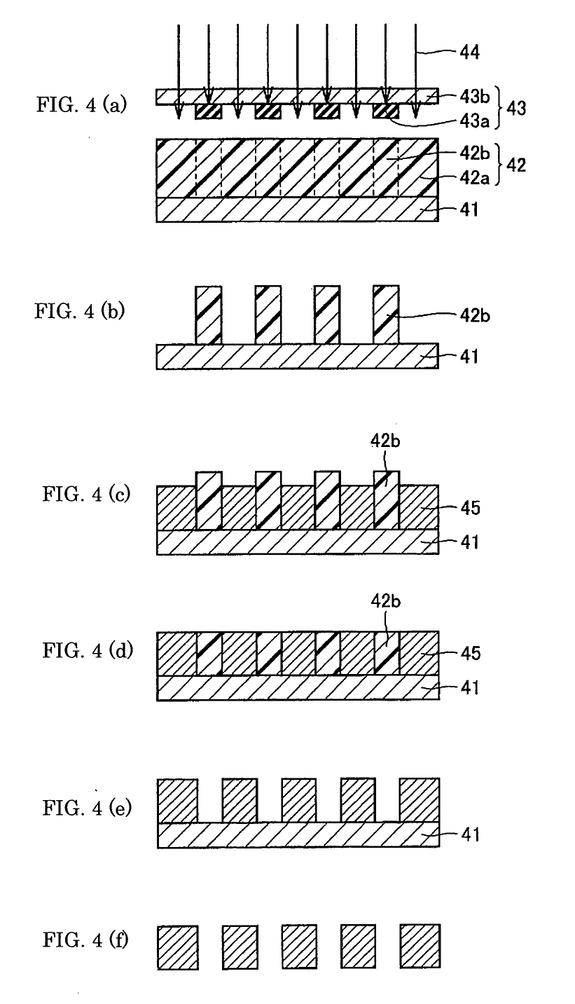

In the manufacturing method of the present invention, a resin layer 42 is formed on an electroconductive substrate 41 as shown in FIG. 4(a). The electroconductive substrate is, for example, a substrate made of metal such as copper, nickel, or stainless steel, or a silicon substrate to which a metallic material such as chrome or titanium is applied by sputtering. The resin layer is made of a resin material containing polyester methacrylate such as polymethyl methacrylate (PMMA) as a main component, or chemical amplification type polymer material having susceptibility to X-rays, or the like. The thickness of the resin layer can be optionally set according to the thickness of the contact to be formed; for example, it can be designed to be 50 μm-500 mm.

Next, a mask 43 is arranged on the resin material 42, and X-rays 44 are irradiated thereto through the mask 43. Preferably, the X-ray is synchrotron radiation. The mask 43 consists of an optically transparent substrate material 43b and an X-ray absorption layer 43a formed according to the pattern of the contact. The optically transparent substrate material 43b is made of silicon nitride, diamond, silicon, titanium or the like. The X-ray absorber layer 43a is made of a heavy metal such as gold, tungsten, or tantalum, or a compound thereof, or the like. A resin layer portion 42a of the resin layer 42 is exposed to the irradiation of X-rays 44, and its quality changes, whereas a resin layer portion 42b is not exposed because of the X-ray absorber layer 43a. Therefore, only the part in which the quality has changed because of the X-rays 44 is removed by the development and consequently a plastic mold (resist structure) 42b is obtained as shown in FIG. 4(b).

Next, a metallic material 45 is deposited by electroforming in the plastic mold (resist structure) 42b as shown in FIG. 4(c). The electroforming means that a layer consisting of a metallic material is formed, using a metallic ion solution, on an electroconductive substrate. The metallic material 45 can be deposited in the plastic mold (resist structure) 42b by electroforming using the electroconductive substrate 41 as a cathode electrode. In a case where the metallic material is deposited to a degree in which the space of the plastic mold (resist structure) is substantially buried, the contact of the present invention can be obtained ultimately from the accumulated metallic material layer. In a case where the metallic material is deposited in the plastic mold (resist structure) beyond the height of the plastic mold (resist structure), a metal microstructure having a space is obtained by removing the plastic mold (resist structure) and the substrate. The metal microstructure thus obtained can be used as a mold in the method of manufacturing a contact according to the present invention as described later. Nickel, copper or their alloy is used as the metallic material, and particularly nickel or a nickel alloy such as nickel manganese is preferable from the viewpoint of enhancing the wear resistance of the contact. After electroforming, the thickness is adjusted to a predetermined measure by polishing or machining (FIG. 4(d)), and thereafter the plastic mold (resist structure) 42b is removed by wet etching or plasma etching as shown in FIG. 4(e). Subsequently, wet etching is performed with acid or alkali, or mechanical processing is performed to remove the electroconductive substrate 41, and thereby a metal microstructure of the present invention can be obtained as shown in FIG. 4(f). Thereafter, a heat treatment is performed at 150° C. -350° C. for 2 hours-48 hours in order to afford spring property. Thus, a contact as shown in FIG. 1 is obtained. If the obtained contact is provided with a layer made of a material having low contact resistance with respect to a convex electrode of electronic equipment or inspection equipment, electrical continuity with the convex electrode of the electronic equipment, etc. can be enhanced. The materials having low contact resistance are a precious metal and an alloy of precious metal, such as Au, Rh, Ag, Ru, Pt, or Pd, or alloys of these materials. If a gold coating is provided with a thickness of 0.05 μm-1 μm, for example, electrical continuity with an electrode of electronic equipment, or the like can be enhanced.

Preferably, one or both faces of a metal microstructure consisting of the above-mentioned metallic material layer are machined so that the thickness thereof is thinner at a position closer to the center, as distanced from the outer periphery. For example, it is preferable that such processing be done in a manner such that one or both faces can be in contact with a spherical surface or paraboloid of revolution.

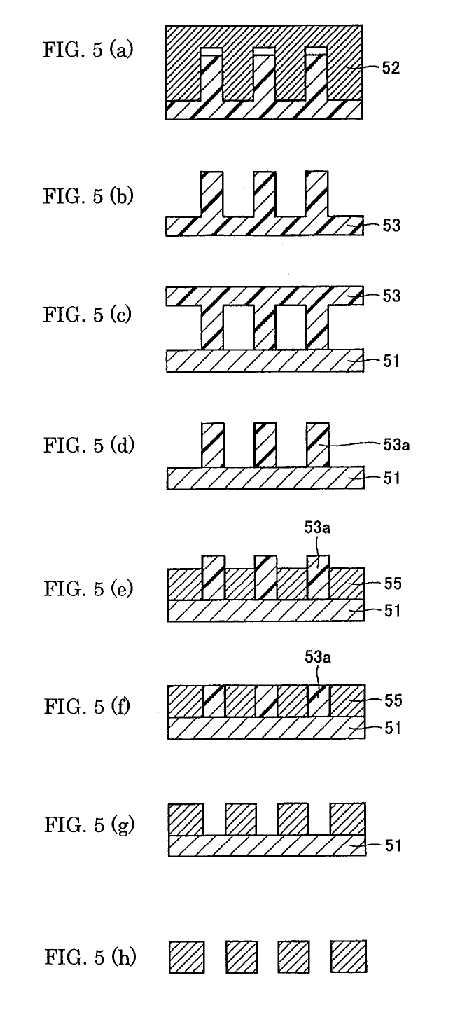

FIGS. 7(b) and 7(c) show examples in which the thickness is made thinner toward the center by processing of one face. In the example of FIG. 7(b), the processed face is in contact with a spherical face 71. In the example of FIG. 7(c), the processed face is in contact with a paraboloid of revolution 72. In the example of FIG. 7(d), the thickness is made thinner toward the center by processing of both faces, and both faces are in contact with a spherical face 73, respectively. Such a bowl-shaped concavity can be formed by machining, etching, or electrical discharge machining, or the like, and from the viewpoint of preciseness, electrical discharge machining is preferable. The electrical discharge machining is performed, for example, in the following manner: the tip of the electrode to be used for electrical discharge machining is processed into a shape of a hemisphere or paraboloid of revolution; and in the case of manufacturing a contact by the above-mentioned method, after electroforming, preferably the metallic layer on the substrate is machined by the electrode whose tip is thus processed, before removing a plastic mold by (resist structure) etching (FIG. 4(d), FIG. 5(f) or after such removing (FIG. 4(e), FIG. 5(g)). A plurality of contacts can be processed together at the same time using an electrode-type mold. The processing of both faces can be made by processing similarly after separating the metallic layer from the substrate.

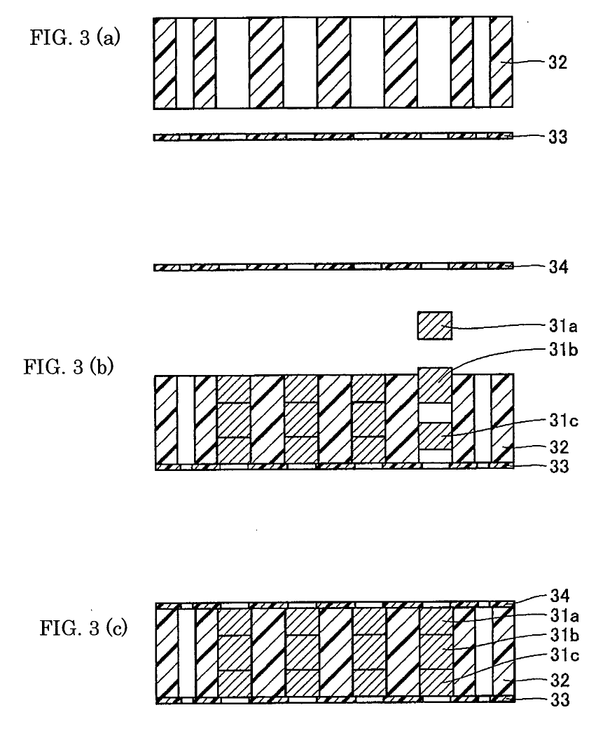

FIGS. 3(a) to 3(c) show a method of manufacturing an inspection socket from contacts. A connector to be mounted in electronic equipment, etc can also be manufactured by a similar method. First, as shown in FIG. 3(a), through-holes are formed in a substrate 32, according to the outer diameter of the contacts which are to be accommodated therein, at the positions corresponding to the electrodes of a semiconductor to be inspected. Subsequently, holes having a diameter smaller than the outer diameter of the contacts to be accommodated are formed in a lower-lid sheet 33 similarly at the positions corresponding to the arrangement of the electrodes, and the lower-cover sheet 33 is attached to the substrate 32. Thereafter, a contact 31c, ring 31b, and contact 31a, in the enumerated order, are engagedly put into each of the through-holes of substrate 32 as shown in FIG. 3(b). Preferably, the ring 31b is manufactured by a method similar to the manufacture of the contacts 31a and 31c, since it is a metal microstructure similar to the contacts. Subsequently, an upper-cover sheet 34 similar to the lower-cover sheet 33 is attached to the substrate 32. Thus, an inspection socket according to the present invention is obtained as shown in FIG. 3(c). The material of the substrate 32, lower-cover sheet 33, and upper-cover sheet 34 is an electrically insulative material such as a polyimide resin or general fiber reinforced plastic (FRP), for example.

The manufacturing method for the inspection socket or the connector to be mounted in electronic equipment or the like is not limited to the method illustrated in FIGS. 3(a) to 3(c). However, the manufacturing method shown in FIGS. 3(a) to 3(c) is preferable because the connector conductor having layer structure can be easily manufactured only by orderly putting contacts and a ring engagedly in the through-hole of the substrate and because the assembly cost is low and the precision is high. The components of such connector conductor are not joined together. Therefore, electrical continuity in the connector conductor is secured by the contact load afforded as a result of contact with an inspection object.

On the other hand, if the components of the connector conductor are joined beforehand, stable electrical continuity within the connector conductor can be secured; thus it is more preferable. The suitable methods for such joining are ultrasonic junction, resistance junction, and electromagnetic pulse junction from the viewpoint of not degrading the spring characteristics of the contact.

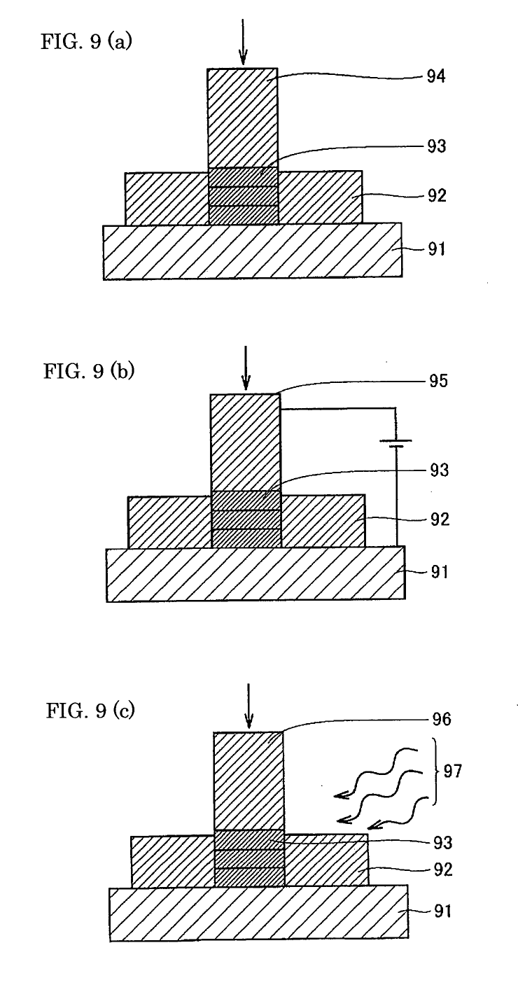

The ultrasonic junction is performed such that, as shown in FIG. 9(a), a fixing jig 92 is arranged on a substrate 91 consisting of Si, etc., components 93 which constitute a connector conductor is stacked in the jig 92, and ultrasonic wave is applied while a pressure is applied through a terminal 94 in the direction indicated by the arrow. The vibration energy generated by the applied ultrasonic wave destroys an oxide film, etc. existing on the junction surface of the components 93 constituting the connector conductor, and consequently, activated metallic atoms combines together. Therefore, it is advantageous, because the residual stress is small since such junction is accomplished at a temperature lower than the fusion temperature of the metal.

From the viewpoint of sufficiently destroying an oxide film on the junction surface, the amount of the pressure to be applied for ultrasonic junction is preferably equal to or more than 1 GPa, and more preferably, equal to or more than 5 GPa. Also, from the viewpoint of avoiding the deformation of these components, depending on the material of the contacts or a ring to be joined, the amount of the pressure is preferably equal to or less than 20 GPa, and more preferably equal to or less than 15 GPa. As for the ultrasonic wave, from the viewpoint of achieving junction efficiently, it is suitable to apply ultrasonic wave of 15 kHz-30 kHz for 0.1 ms-10 ms.

The resistance junction is performed such that, as shown in FIG. 9(b), an insulative jig 92 is placed on an electroconductive substrate 91, components constituting the connector conductor 93 are stacked in the jig 92, and a voltage is applied while a pressure is applied through an electrode 95 in the direction indicated by the arrow. The temperature of the junction part of the components constituting the connector conductor 93 is increased because of the heat generated by resistance due to an electric current, and thereby components constituting the connector conductor 93 are joined under the applied pressure. The resistance junction is performed preferably by applying a pressure of 20 Mpa or less and an electric current of 0.01 A-50 A for 0.01 ms-10 ms.

The electromagnetic junction is performed such that, as shown in FIG. 9(c), the jig 92 is placed on the substrate 91, the components constituting the connector conductor 93 are stacked in the jig 92, and electromagnetic wave 97 is irradiated while a pressure is applied through a rod 96 in the direction of the arrow. The temperature of a junction part is increased by irradiating electromagnetic wave having the absorption wavelength that is peculiar to components constituting the connector conductor 93 or the eutectic material formed on the junction surface, and junction is made under the applied pressure. For example, when the contact and ring are made of Ni, or when the eutectic material to be formed on the junction surface is Au or a solder, it is preferable to apply a pressure of 1 MPa-40 MPa and to irradiate electromagnetic wave of 0.1 nm-a 560 nm for 1 ms-10000 ms.

FIGS. 9(a) to 9(c) illustrate examples of the case where the connector conductor consists of two contacts and a ring interposed therebetween. However, in the case of the connector conductor consisting of two contacts, junction can be made in a similar manner.

If a junction surface is provided beforehand with a layer consisting of a material which is eutectic relative to elements to be joined such as the contact or ring, the junction can be made with low energy, and it is desirable from the view point of restraining the occurrence of deformation and displacement during junction work. Since Ni or Ni alloy preferably is used as a material of elements to be joined, Au or Sn is preferable as a eutectic material. An Au or Sn layer can be formed on the junction surface by coating. It is possible, for example, to thereby enhance electrical continuity if junction is made in a manner such that prior to junction the surface of a contact is provided with a layer made of a material having low contact resistance with respect to the convex electrode of electronic equipment or inspection equipment, and a ring is provided with a layer consisting of a material that is eutectic relative to the contact.

A method of manufacturing a contact according to another embodiment of the present invention includes a process of forming a plastic mold (resist structure) with a metal mold and a process of forming a layer consisting of metallic material in the plastic mold (resist structure) by electroforming. With such method also, as in the case of the above-mentioned manufacturing method in which a plastic mold (resist structure) is formed by X-ray lithography, it is possible to fabricate at low cost an inspection contact or coupling contact exhibiting high reliability and capable of attaining electrical continuity of large electric current. The method of the present invention in which a mold is used is advantageous in that a mass production of contacts is possible using the same mold.

In such manufacturing method, a depressed plastic mold (resist structure) 53 as shown in FIG. 5(b) is formed by press or injection molding or the like using a mold 52 having a convex portion as shown in FIG. 5(a). Thermoplastic resins, including acrylic resins such as polymethyl methacrylate, polyurethane resin, or polyacetal resin such as polyoxymethylene, are used as the material of the plastic mold (resist structure). As for the mold 52, since it is a metal microstructure similar to the contact of the present invention, it is formed preferably by the above-mentioned method in which an X-ray lithography method and electroforming are combined.

Next, after reversing the top and the bottom of the plastic mold (resist structure) 53, it is attached on the electroconductive substrate 51 as shown in FIG. 5(c). Subsequently, the plastic mold (resist structure) 53 is polished to form a plastic mold (resist structure) 53a as shown in FIG. 5(d). The subsequent processes are the same as described above: a metallic material 55 is deposited to the plastic mold (resist structure) 53a by electroforming (FIG. 5(e)), the thickness is adjusted (FIG. 5(f)), the plastic mold (resist structure) 53a is removed (FIG. 5(g)), and the electroconductive substrate 51 is removed, and thereby a metal microstructure as shown in FIG. 5(h) is obtained. Thereafter, a spring property is afforded and a contact of the present invention is obtained as shown in FIG. 1. A socket for inspection equipment or a connector for electronic equipment is obtained from such contacts by the same method as described above. The ring can be made, as in the case of making the contact, through the process of forming a plastic mold (resist structure) with a metal mold and the process of forming a layer consisting of a metallic material in the plastic mold (resist structure) by electroforming, and preferably the ring is provided with an Au coating with the thickness of 0.05 μm-1 μm in order to enhance electrical continuity.

### EXAMPLE 1

First, a resin layer 42 was formed on an electroconductive substrate 41 as shown in FIG. 4(a). A silicon substrate made by sputtering titanium was used as the electroconductive substrate. The material for forming a resin layer was a copolymer of methyl methacrylate and methacrylic acid, and the thickness of the resin layer was 150 μm.

Next, a mask 43 was arranged on the resin layer 42, and X-rays 44 were irradiated through the mask 43. As for the X-ray, synchrotron radiation by SR equipment was adopted. The mask 43 had an X-ray absorber layer 43a corresponding to the pattern of the contact, and an optically transparent substrate material 43b of the mask 43 was consisted of silicon nitride, and the X-ray absorber layer 43a was made of tungsten nitride.

After the irradiation of X-rays 44, development was performed by methyl isobutyl ketone, and the part in which the quality has been changed by the X-rays 44 was removed. As a result, a plastic mold (resist structure) 42b as shown in FIG. 4(b) was obtained. Then, as shown in FIG. 4(c), a metallic material 45 was deposited by electroforming in the space of the plastic mold (resist structure) 42b. Nickel was used as the metallic material. After the electroforming was completed, the unevenness of the surface was eliminated by polishing as shown in FIG. 4(d), and the plastic mold (resist structure) 42b was removed by oxygen plasma as shown in FIG. 4(e). Subsequently, the electroconductive substrate 41 was removed by wet etching with KOH solution. Thus, a continuous metal microstructure as shown in FIG. 4(f) was obtained.

Thereafter, gold coating of 0.1 μm thickness was made after applying a heat treatment to the metal microstructure. Thus, a columnar contact of the present invention having a spiral spring structure as shown in FIG. 1 was obtained. The contacts thus obtained had a diameter D of 120 μm and a thickness b of 100 μm. The thickness a of the spring was 10 μm and the aspect ratio (b/a) was 10. The number of spirals was 3.5 turns, and the stroke of the spring was 40 μm. On the other hand, rings having an outer diameter of 120 μm and the thickness of 100 μm were manufactured by the same method as the contacts.

Subsequently, as shown in FIG. 3(a), the lower-cover sheet 33 was attached to the substrate 32, which had through-holes corresponding to the positions of the electrodes of a semiconductor (LSI) to be inspected. The substrate 32 was made of a polyimide resin and had the thickness of 300 μm, and through-holes having a diameter of 120 μm were formed therein. Also, the lower-cover sheet 33 was made of a polyimide resin, and had the thickness of 20 μm, in which holes having a diameter of 100 μm were formed at the positions corresponding to the through-holes of substrate 32.

Next, as shown in FIG. 9(a), the fixing jig 92 was placed on the substrate 91 made of Si, and a contact, ring, and contact were stacked in order in the space of jig 92, and ultrasonic wave of 20 kHz was applied for 1 ms while a pressure of 5 GPa was applied through the terminal 94, and thus they were joined together. The connector conductors thus obtained were engaged in the through-holes of the above-mentioned substrate made of polyimide resin, and an upper-cover sheet similar to the lower-cover sheet was attached to the substrate. Thus, the inspection socket of the present invention was completed.

The inspection socket thus obtained was put, as shown in FIG. 2(a), between the transformer former 28 of the inspection equipment and an LSI 25 to be inspected. When a pressure of 70 mN force was applied in this state in the direction indicated by the arrows as shown in FIG. 2(a), the contacts were transformed according to the shape of ball-like convex electrodes, and electrical continuity was attained between the convex electrodes 26 of LSI 25 and the convex electrodes 27 of a transformer 28 because of the additive force of the spiral spring, and the LSI could be inspected based on electrical signals thus obtained. In this example, the diameter D of the contact was 120 μm, which was found to be sufficiently small so that such contacts can be able to comply with the high density packaging of electronic equipment.

### EXAMPLE 2

An inspection socket was fabricated in a manner similar to the method of Example 1 except that a connector conductor was formed by resistance junction instead of ultrasonic junction of Example 1. The resistance junction was performed in a manner such that, as shown in FIG. 9(b), the insulative jig 92 was placed on the electroconductive substrate 91, components constituting the connector conductor 93 were stacked in the jig 92, an electric current of 40 A was applied for 0.5 ms while a pressure of 7 MPa was applied through the electrode 95 in the direction of the arrow.

As in the case of Example 1, the connector conductors thus obtained were engaged in the through-holes of the substrate made of polyimide resin, and an upper-cover sheet similar to the lower-cover sheet was attached to the substrate. Thus, the inspection socket of the present invention was obtained.

The inspection socket thus obtained was put, as shown in FIG. 2(a), between the transformer former 28 of the inspection equipment and an LSI 25 to be inspected. When a pressure of 70 mN force was applied in this state in the direction indicated by the arrows as shown in FIG. 2(a), the contacts were transformed according to the shape of ball-shaped convex electrodes, and electrical continuity was attained between the convex electrodes 26 of LSI 25 and the convex electrodes 27 of a transformer 28 because of the additive force of the spiral spring, and the LSI could be inspected based on electrical signals thus obtained.

### EXAMPLE 3

An inspection socket was fabricated in a manner similar to the method of Example 1 except that a connector conductor was formed by electromagnetic junction instead of ultrasonic junction of Example 1. The electromagnetic junction was performed in a manner such that, as shown in FIG. 9(c), the jig 92 was placed on the substrate 91, components constituting the connector conductor 93 were stacked in the jig 92, and electromagnetic wave 97 of 0.4 nm was irradiated for 500 ms while a pressure of 20 MPa was applied through a rod 96 in the direction of the arrow.

As in the case of Example 1, the connector conductors thus obtained were engaged in the through-holes of the substrate made of polyimide resin, and an upper-cover sheet similar to the lower-cover sheet was attached to the substrate. Thus, the inspection socket of the present invention was obtained. As in the case of Example 1, the inspection socket thus obtained was put between inspection equipment and an object to be inspected, and the contacts were pressed so as to be transformed according to the shape of ball-shaped convex electrodes such that electrical continuity was attained between an LSI and a transformer because of the additive force of the spiral spring, and the LSI could be inspected based on electrical signals thus obtained.

It should be noted that the embodiments and the examples disclosed in this specification are exemplary in all respects and that the present invention is not limited to them. It is intended that the scope of the present invention be shown by the claims rather than the description set forth above and include all modifications and equivalents to the claims.

According to the present invention, it is possible to provide inspection equipment or electronic equipment having low-cost contacts exhibiting high reliability and capable of attaining electrical continuity of large electric current.

1. A method of manufacturing a columnar contact having a spiral spring structure, the shape of the contact being transformed by being pressed onto a convex electrode of electronic equipment or inspection equipment such that electrical continuity is attained between the contact and the convex electrode, the method comprising the steps of:
forming a plastic mold (resist structure) with a metal mold; and
forming a layer consisting of metallic material in the plastic mold (resist structure) by means of electroforming.

2. A method of manufacturing a columnar contact having a spiral spring structure, the shape of the contact being transformed by being pressed onto a convex electrode of electronic equipment or inspection equipment such that electrical continuity is attained between the contact and the convex electrode, the method comprising the steps of:
forming a plastic mold (resist structure) by X-ray lithography; and
forming a layer consisting of metallic material in the plastic mold (resist structure) by means of electroforming.

3. A method of manufacturing a contact according to claim 1, further comprising the step of machining one or both faces of said layer consisting of metallic material so that the thickness of said layer consisting of metallic material becomes thinner from the outer periphery to the center.

4. A method of manufacturing a contact according to claim 2, further comprising the step of machining one or both faces of said layer consisting of metallic material so that the thickness of said layer consisting of metallic material becomes thinner from the outer periphery to the center.

5. A method of manufacturing a contact according to claim 3, wherein said step is performed by electrical discharge machining.

6. A method of manufacturing a contact according to claim 4, wherein said step is performed by electrical discharge machining.

7. A method of manufacturing a contact according to claim 3, wherein said machining process is performed in a manner such that one or both faces of said layer consisting of metallic material can be in contact with a spherical face or paraboloid of revolution.

8. A method of manufacturing a contact according to claim 4, wherein said machining process is performed in a manner such that one or both faces of said layer consisting of metallic material can be in contact with a spherical face or paraboloid of revolution.

9. A method of manufacturing a contact according to claim 1, wherein said contact is made of nickel or nickel alloy.

10. A method of manufacturing a contact according to claim 2, wherein said contact is made of nickel or nickel alloy.

11. A contact manufactured by a method set forth in claim 1.

12. A contact manufactured by a method set forth in claim 2.

13. A connector conductor comprising contacts arranged at both ends thereof and having a space between the contacts so that the spring of a contact can perform a stroke.

14. A connector conductor according to claim 13, further comprising a ring interposed between the contacts.

15. A connector conductor according to claim 13, comprising two contacts fabricated by a method set forth in claims 3.

16. A connector conductor according to claim 13, comprising two contacts fabricated by a method set forth in claims 4.

17. A connector conductor as set forth in claim 13, wherein the connector conductor is structured such that a contact and another contact, or a contact and a ring, are connected together without being bonded.

18. A connector conductor as set forth in claim 13, wherein the connector conductor is structured such that a contact and another contact, or a contact and a ring, are connected together with being bonded.

19. A connector conductor as set forth in claim 18, wherein a contact and another contact, or a contact and a ring, are bonded by ultrasonic junction, resistance junction, or electromagnetic junction.

20. A connector conductor as set forth in claim 18, wherein a junction surface of a component thereof is provided with a layer consisting of a material having eutectic property with respect to the material of another component to be bonded before such bonding is done between the components.

21. A connector conductor as set forth in claim 20, wherein, prior to such bonding, a layer consisting of a material having low contact resistance with respect to the convex electrode of electronic equipment or inspection equipment is formed on the contact and a layer consisting of material having eutectic property with respect to the material of the contact is formed on the ring.

22. A socket having connector conductors set forth in claim 13, the connector conductors being provided in insulative through-holes of a substrate, wherein the socket is an inspection socket used for inspecting a semiconductor of land grid array arrangement.

23. Inspection equipment having a socket set forth in claim 22.

24. A connector having connector conductors set forth in claim 13, the connector conductors being provided in insulative through-holes of a substrate, wherein the connector is used for connection with land electrodes.

25. Electronic equipment having a connector set forth in claim 24.
